(19) United States
(12) Patent Application Publication
(10) Pub. No.: US 2022/0005777 A1
(43) Pub. Date: Jan. 6, 2022

(54) SEMICONDUCTOR ASSEMBLY WITH DISCRETE ENERGY STORAGE COMPONENT

(71) Applicant: Smoltek AB, Göteborg (SE)

(72) Inventors: M Shafiqul Kabir, Västra Frölunda (SE); Vincent Desmaris, Göteborg (SE); Rickard Andersson, Göteborg (SE); Muhammad Amin Saleem, Göteborg (SE); Maria Bylund, Göteborg (SE); Anders Johansson, Öckerö (SE); Fredrik Liljeberg, Göteborg (SE); Ola Tiverman, Västra Frölunda (SE)

(21) Appl. No.: 17/289,060

(22) PCT Filed: Nov. 20, 2019
(86) PCT No.: PCT/SE2019/051176

§ 371 Date: Apr. 27, 2021

(30) Foreign Application Priority Data
Nov. 26, 2018 (SE) 1851460-4

(51) Int. Cl. H01L 23/00; H01L 25/065; H01L 25/10; H01L 49/02

(52) U.S. Cl. CPC H01L 24/08; H01L 25/0657; H01L 25/105; H01L 28/60; H01L 2225/0651; H01L 2924/19104; H01L 2225/06582; H01L 2225/1035; H01L 2225/1058; H01L 2224/08145; H01L 2924/19041; H01L 2225/06568

(57) ABSTRACT

A semiconductor assembly, comprising: a first semiconductor die including processing circuitry and pads, said first semiconductor die having a first surface and a second surface opposite the first surface; a second semiconductor die including memory circuitry and pads, said second semiconductor die being arranged on one of the first surface and the second surface of said first semiconductor die, and pads of said second semiconductor die being coupled to pads of said first semiconductor die; and at least a first capacitor having terminals, said first capacitor being arranged on one of the first surface and the second surface of said first semiconductor die and the terminals of said capacitor being coupled to pads of said first semiconductor die.

### FIELD OF THE INVENTION

The present invention relates to a semiconductor assembly, and to an electronic component including such a semiconductor assembly.

### BACKGROUND OF THE INVENTION

Miniaturization of electronics has been the trend for many decades which has enabled us to witness different kinds of appliances with many functionalities. To a large part, this progress was enabled by miniaturizing and integrating transistors, resistors and capacitors for logic applications onto silicon. By comparison, passive components (resistors, capacitors, and inductors) at the circuit-board level have made only incremental advances in size and density. As a consequence, passive components occupy an increasingly larger area and mass fraction of electronic systems and are a major hurdle for further miniaturization of many electronic systems with lower system cost. Current smartphones typically use more than 1000 discrete capacitor components. A circuit board of an electric car utilizes roughly 10000 such discrete capacitor components and trend is upwards. The need for such large numbers of capacitors is primarily driven by the need to tackle the problem with power management systems driving the power all the way from the source of energy (battery/mains power) through the packaging schemes (PCB/SLP/SoC/SiP) to the functional silicon chip/die, and to the on chip integrated circuits. There are different power management problems to tackle at different stages of integrations of such appliances.

Miniaturization of silicon circuits has enabled us to achieve more functions per unit area. Such achievements have come with a price and have stressed the power management system of the die to the extreme. Today's silicon chips suffer heavily from power noise induced by leakage current from the transistors, high frequency reflections in the interconnect grids, parasitics switching noise etc. along the power grid. Such power noise can cause voltage fluctuation and impedance mismatch of the circuit and may result in gate delay and logic errors, jitter, etc. and can be catastrophic. It is a vast area of research on how to tackle such on-chip power management solutions. One of the ways to tackle such problem is to use metal insulator metal (MIM) decoupling capacitors integrated with the circuit. However, such integrated schemes to tackle the problems inside of a die is limited by white space (expensive real estate space available on die) to integrate decoupling capacitors on the surface of the die. It is reported that the white space decreasing and that only about 10% is allocated in today's generation per die, for on chip decoupling capacitors.

Therefore, there is a need for increasing the capacitance density of such decoupling capacitors within the stipulated 2D area. Some solutions are proposed and demonstrated in A. M. Saleem et al., ‘Integrated on-chip solid state capacitor based on vertically aligned carbon nanofibers, grown using a CMOS temperature compatible process’, Solid State Electronics, vol. 139, 75 (January 2018), and in EP2074641. The prior arts have shown improvements of the capacitive values with respect to traditional MIM capacitors. The demonstrated devices are, however, prone to suffer from the parasitic capacitances from the field oxide present on the contact points, or from the nanostructure growing randomly outside of the device area causing unintentional and uncontrolled parasitic effects (capacitive/resistive/inductive) to be present in the device which will cause detrimental effects for circuit implementation. A lot of design and processing improvement steps are anticipated to be needed (for example CMP planarization processing, field oxide removal etc.) to make such device free of parasitics which essentially diminishes the benefits of such technology concepts for practical implementations.

Looking from another angle of view—the printed circuit board (PCB) or substrate like pcb (SLP) board level—the power supply rails (e.g., ±2.5V, ±12V or 3.3V etc) providing the power in most cases are produced by linear power supply or switch mode power supply techniques. Despite that they both have rectification and filtering or regulation stage prior to feeding to the power grid of the electronic circuits, they still may possess ripple noise. Hence a lot of capacitors are typically found on the board, and the quantity and value of capacitors become higher as the switching frequency of the IC rises. Moreover, the power supply requirements and noise margins are becoming more and more stringent as the power supply requirements of ICs are progressing towards lower operating voltages. Additionally, with advancement in the system level packaging like SoC/SiP, FOWLP/FIWLP/Chiplet wafer level packaging of dissimilar ICs/heterogeneous integrations, power management is becoming a dominant issue. Noise may occur in the voltage levels either due to poor power supply regulation, length/shape of PCB power interconnects, wire parasitics, switching frequencies of ICs and EMI effects etc. For such complex integrated packages, capacitors closer to the different ICs are required for better performances.

Today's industry standard MLCC/TSC/LICC capacitor technologies to manufacture such discrete components are challenged to comply with the increasing demand for lower height (Z height) to be sub 100 μm and preferably below 20 μm. This demand is due to the fact that the ICs that are integrated in packaging SoC/SiP packaging require sub 70 μm height of the capacitor to accommodate between the SoC/SiP packaging solutions due to decrease in the bumps interconnects heights and pitch/spacing.

To circumvent this issue, US20170012029 demonstrates embodiments to accommodate a MIM capacitor configuration at the back side of a die. Such a scheme, however, needs to be CMOS compatible and must be done on every die that is to be assembled. This may entail the limitations of such technology concepts due to adaptation complexities of such MIM structure in different technology nodes and costs associated with such implementation. This may essentially increase the cost per die substantially and may slay the cost benefits per function that is needed at a packaging level.

MLCC is the most prominent type of discrete capacitor component used in the world. Trillions of such discrete components are used every year in any given system/gadget/appliances. There has been some progress in miniaturizing of these components and the thinnest that can be found commercially is claimed by Taiyo Yuden to be 110 μm. Samsung ElectroMechanical system have introduced the concept of LICC to reduce the thickness and reach lower ESL (Equivalent Series Inductance) even further. Ipdia (now part of Murata) has introduced TSC discrete capacitor component to be as thin as 80 μm with a staggering capacitance value exceeding 900 nF/mm2. However, MLCC, LICC and TSC are prone to struggle to going down in Z dimension (height) further due to materials involved (raw metal/dielectric particles), processing schemes (sintering/silicon etching) and cost of raw materials and processing. ((MLCC process requires a thorough understanding of the limitations of the raw materials used in capacitor manufacturing, including copper, nickel, silver, gold, tantalum, barium titanate, alumina etc. It is also known that the ceramic class 2 MLCC suffers negatively under temperature variations, applied voltage and over time (aging) results in significant degradation of capacitance values from the originally stipulated capacitance values by the vendors. Such degradation can affect adversely any sub-system related to security of a system (e.g. electric car).

Further miniaturization of these components based on those established technologies thus may not be as cost competitive as it was before. It is particularly challenging to match with the need to be small enough both in 2D and in 3D space such that the discrete capacitor components can fit between the flip chip bumps interconnects without compromising the cost.

Discrete capacitor components need to be produced in trillions to fulfil the industrial demand and CMOS compatible technologies are simply cost prohibitive to be exploited for producing discrete components with respect to MLCC or LICC or TSC.

The on-going strive towards more and more computationally capable electronic devices, requires more compact electronic circuit integration, including vertical stacking of semiconductor dies in packaged electronic components. In the near future, sufficient and uniform supply of power to processing circuitry is expected to be an important limitation to the overall capabilities of electronic components.

It would therefore be desirable to enable improved supply of power to processing circuitry in a semiconductor assembly. In particular, it would be desirable to enable more stable supply of power.

### SUMMARY

In view of the above, it is an object of the present invention to enable improved supply of power to processing circuitry in a semiconductor assembly, in particular more stable supply of power.

According to an aspect of the present invention, it is therefore provided a semiconductor assembly, comprising: a first semiconductor die including processing circuitry and pads, said first semiconductor die having a first surface and a second surface opposite the first surface; a second semiconductor die including memory circuitry and pads, said second semiconductor die being arranged on one of the first surface and the second surface of said first semiconductor die, and pads of said second semiconductor die being coupled to pads of said first semiconductor die; and at least a first energy storage component having terminals, said first energy storage component being arranged on one of the first surface and the second surface of said first semiconductor die and the terminals of said energy storage component being coupled to pads of said first semiconductor die.

According to an aspect of the present invention, it is therefore provided a semiconductor assembly, comprising: a first semiconductor die including processing circuitry and pads, said first semiconductor die having a first surface and a second surface opposite the first surface; a second semiconductor die circuitry and pads, said second semiconductor die being arranged on one of the first surface and the second surface of said first semiconductor die, and pads of said second semiconductor die being coupled to pads of said first semiconductor die; and at least a first energy storage component having terminals, said first energy storage component being arranged on one of the first surface and the second surface of said first semiconductor die and the terminals of said energy storage component being coupled to pads of said first semiconductor die.

The second semiconductor die may be a digital circuit, a RF circuit, a sensor or any other functional die to provide a specific functionality.

In accordance with the present invention, a semiconductor assembly may have as many die as required to form the functional assembly, for example, in the form of an SoC or SiP.

The present invention is based upon the realization that the desired sufficient and more uniform delivery of power to processing circuitry in a vertically stacked semiconductor assembly can be achieved by connecting at least one energy storage component, advantageously a capacitor directly to a surface of the semiconductor die including the processing circuitry.

This provides for shorter conductor lengths between the processing circuitry and the terminals of the energy storage component, which in turn reduces inductive loads and parasitics, and improves the temporal uniformity of the supply of power to the processing circuitry.

According to another aspect of the present invention, it is provided a semiconductor assembly, comprising: a first semiconductor die including processing circuitry and pads, said first semiconductor die having a first surface and a second surface opposite the first surface; a second semiconductor die including memory circuitry and pads, said second semiconductor die being coupled with one of the first surface and the second surface of said first semiconductor die, and pads of said second semiconductor die being coupled to pads of said first semiconductor die; and at least a first energy storage component having terminals, said first energy storage component being arranged on one of the first surface and the second surface of said first semiconductor die and the terminals of said energy storage component being coupled to pads of said first semiconductor die.

In embodiments, the processing circuitry may be provided in separate so-called cores. In such embodiments, each core may be provided with its own energy storage component, such as capacitor. One energy storage component with several separately addressable energy storage components may serve several cores.

According to embodiments, the at least first energy storage component may be a nanostructure-based energy storage component, which may be made with a profile height below 100 μm in height.

Advantageously, the at least first energy storage component may be an at least first capacitor.

Advantageously, the at least one energy storage component may be used for decoupling purposes.

Advantageously, the at least one energy storage component may be used for filtering purposes.

Advantageously, the at least one energy storage component may be a battery.

Advantageously, the nanostructures may be “non-horizontally” grown, such as generally vertically grown. The nanostructures may be generally straight, spiraling, branched, wavy or tilted.

Moreover, the semiconductor assembly according to embodiments of the present invention may advantageously be comprised in an electronic component, further comprising a carrier having at least a first set of carrier pads on a first carrier surface. Pads of said first semiconductor die may be coupled to said first set of carrier pads.

In embodiments, the carrier may comprise one or several energy storage components, which may be arranged on or embedded in the carrier.

The one or several energy storage components comprised in the carrier may also be nano-structure based.

According to another aspect of the present invention, it is provided a circuit board comprising: a first circuit board layer; and a second circuit board layer layered with the first circuit board layer, the second circuit board layer including a conductor pattern, at least one discrete energy storage component, and a dielectric material embedding the conductor pattern and the discrete energy storage component.

Embodiments of the present invention can fulfil the requirement of (a) very high electrostatic or electrochemical capacitance value per unit area/volume, (b) low profile in 2D and Z direction, (c) surface mount compatible and suitable for 2D, 2.5D and 3D packaging/assembly/embedded technologies, (d) easy to design form factor, (e) Stable and robust performance against temperature and applied voltages (f) low equivalent series inductance (ESL) per square, (g) longer life time or enhanced life cycle without capacitive degradation and (h) cost effective.

### BRIEF DESCRIPTION OF THE DRAWINGS

These and other aspects of the present invention will now be described in more detail, with reference to the appended drawings showing an example embodiment of the invention, wherein:

FIG. 1 schematically shows an example electronic device, here in the form of a mobile phone, including an electronic component according to an example embodiment of the present invention;

FIG. 2 is a schematic illustration of a first embodiment of the semiconductor assembly according to the present invention;

FIG. 3 is a schematic illustration of a second embodiment of the semiconductor assembly according to the present invention;

FIG. 4 is an exploded view of an electronic component including the semiconductor assembly in FIG. 3;

FIG. 5 is a schematic illustration of an energy storage component according to an example embodiment of the present invention;

FIG. 6 is an enlarged illustration of a first example MIM-arrangement for a MIM-capacitor component; and

FIG. 7 is an enlarged illustration of a second example MIM-arrangement for a MIM-battery component.

### DETAILED DESCRIPTION OF EXAMPLE EMBODIMENTS

In the present detailed description, example embodiments of the semiconductor assembly according to the present invention are mainly described as including semiconductor dies that are flip-chip connected to each other, and discrete capacitor components connected to pads of the semiconductor assembly. It should be noted that many other configurations are included in the scope defined by the claims. For instance, many other ways of interconnecting semiconductor dies are foreseen, including wire-bonding, direct die bonding etc. Furthermore, one or several capacitors may be formed directly on one or more of the semiconductor dies. Stacking of more than one capacitor on each other to form a stack of capacitors is also anticipated according to the present invention.

According to embodiments, the energy storage device(s) may be provided in the form of a nanostructure electrochemical storage or battery. In these embodiments, the conduction controlling material involves primarily ions as part of the energy storage mechanism present in the conduction controlling material, such as by providing for energy storage by allowing transport of ions through the conduction controlling material. Suitable electrolytes may be solid or semi-solid electrolytes, and may be chosen forms of solid crystals, ceramic, garnet or polymers or gel to act as electrolyte e.g. strontium titanate, yttria-stabilized zirconia, PMMA, KOH, lithium phosphorus oxynitride, Li based composites etc. The electrolyte layer may include a polymer electrolyte. The polymer electrolyte may include a polymer matrix, an additive, and a salt.

The conduction controlling electrolyte materials may be deposited via CVD, thermal processes, or spin coating or spray coating or any other suitable method used in the industry.

According to embodiments of the invention, the conduction controlling material may comprise a solid dielectric and an electrolyte in a layered configuration. In such embodiments, the energy storage component may be seen as a hybrid between a capacitor-type (electrostatic) and a battery-type (electrochemical) energy storage device. This configuration may provide for a higher energy density and power density than a pure capacitor component and faster charging than pure battery component.

Although energy storage device components in the form of capacitor components are mainly discussed below, it should be noted that the teachings herein are equally applicable for energy storage device components in the form of nanostructure electrochemical storage devices or the above-described hybrid component. It is also anticipated to use more than one energy storage discrete component to be used to fulfill different functionality for example, filtering, decoupling, storage etc.

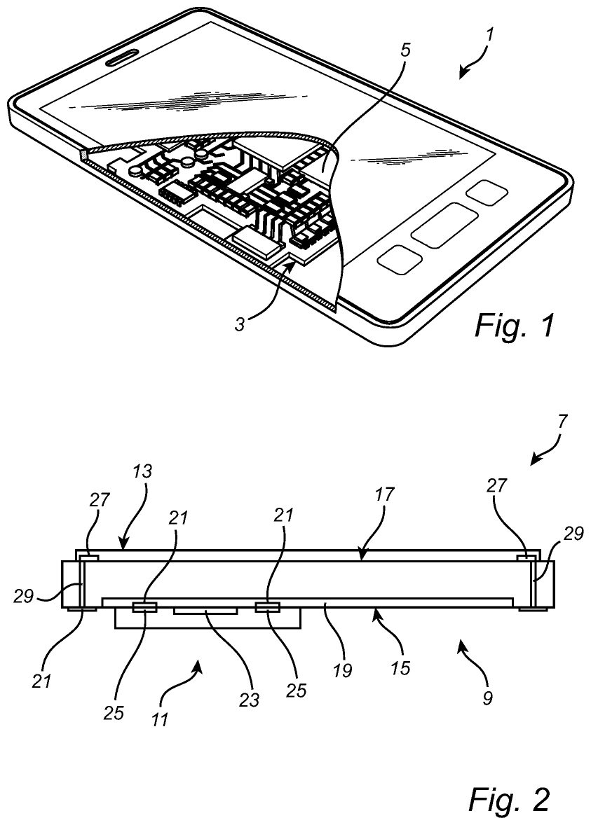

FIG. 1 schematically illustrates an electronic device according to an embodiment of the present invention, here in the form of a mobile phone 1. In the simplified and schematic illustration in FIG. 1, it is indicated that the mobile phone, like most electronic devices, comprises a circuit board 3, populated with electronic components 5. Although shown here in the form of a mobile phone, it should be understood that the electronic device according to embodiments of the present invention may equally well be any other electronic device, such as a laptop/computer, a tablet computer, a smart watch, gaming box, an entertainment unit, a navigation device, communication device, a personal digital assistant (PDA), a fixed location data unit etc.

At least some of the electronic components 5 in FIG. 1 may be complex components, including at least one semiconductor assembly with vertically stacked semiconductor dies.

One such semiconductor assembly 7, according to a first example embodiment of the present invention is schematically illustrated in FIG. 2.

Referring to FIG. 2, the semiconductor assembly 7 comprises a first semiconductor die 9, a second semiconductor die 11, and a capacitor 13. The first semiconductor die 9 has a first surface 15 and a second surface 17 opposite the first surface 15. Processing circuitry 19 and pads 21 are formed on the first surface 15 of the first semiconductor die 9. The second semiconductor die 11 comprises memory circuitry 23 and pads 25. As is schematically shown in FIG. 2, the second semiconductor die 11 is here arranged on the first surface 15 of the first semiconductor die 9, and pads 25 of the second semiconductor die 11 are connected to pads 21 of the first semiconductor die 9. It should be noted that pads of any one of the first 9 and second 11 semiconductor die may be provided in a redistribution layer (RDL), which may be formed using so-called wafer level fan-out (WLFO) technology. The capacitor 13 is attached to the second surface 17 of the first semiconductor die 9, and has terminals 27 connected to pads 21 of the first semiconductor die 9. In the example configuration in FIG. 2, the terminals 27 of the capacitor 13 are connected to pads 21 of the first semiconductor die 9 using through silicon vias (TSVs) 29. Although only two capacitor terminals 27 have been illustrated in FIG. 2, it should be understood that the capacitor 13 may have additional terminals, which may be connected to other pads of the first semiconductor die 9. For example, decoupling of inputs and/or outputs of the first semiconductor 9 may be provided by the terminals of the capacitor 13. Furthermore, different cores of the processing circuitry 19 may be buffered by different functional capacitors that may be comprised in the capacitor 13. As will be immediately evident to those skilled in the relevant art, the arrangement of the capacitor 13 in FIG. 2 provides for extremely short connectors between the processing circuitry and the capacitor(s) providing very small inductive loads and parasitic capacitances, which in turn provides for uniform power supply to the processing circuitry for high processing speed.

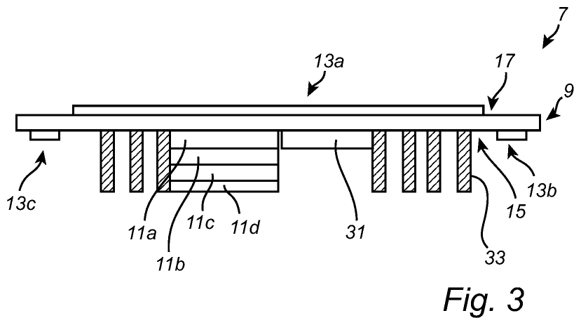

FIG. 3 schematically shows a second embodiment of the semiconductor assembly 7 according to the present invention. To avoid cluttering the drawing, FIG. 3 is shown with somewhat less detail than FIG. 2.

Referring to FIG. 3, the semiconductor assembly 7 in this second example embodiment comprises a third semiconductor die 31 arranged on the first semiconductor die 9. Although not shown in FIG. 3, it should be understood that pads of the third semiconductor die 31 are connected to pads of the first semiconductor die 9. The third semiconductor die 31 may, for example, advantageously comprise power management circuitry and/or transceiver circuit and/or location sensor circuitry and/or other types of sensing circuitry and/or MEMS sensor devices.

As described above for the first example embodiment of the semiconductor assembly 7 shown in FIG. 2, the semiconductor assembly 7 according to the second example embodiment comprises a relatively large first capacitor 13a arranged on the second 17 surface of the first semiconductor die 9. In addition, the semiconductor assembly 7 in FIG. 3 comprises second 13b and third 13c capacitors arranged on the first 15 surface of the first semiconductor die 9.

Furthermore, the semiconductor assembly 7 in FIG. 3 comprises a stack 11a-d of second semiconductor dies, typically memory dies, such as NRAM or DRAM.

To facilitate integration of the semiconductor assembly 7 in an electronic component 5, vertical connectors 33 are arranged on the first surface 15 of the first semiconductor die 9. As is well-known to those of ordinary skill in the relevant art, there are several ways of achieving such vertical connectors 33, including, for example, conductive pillars (copper pillars) or stud-bumps etc.

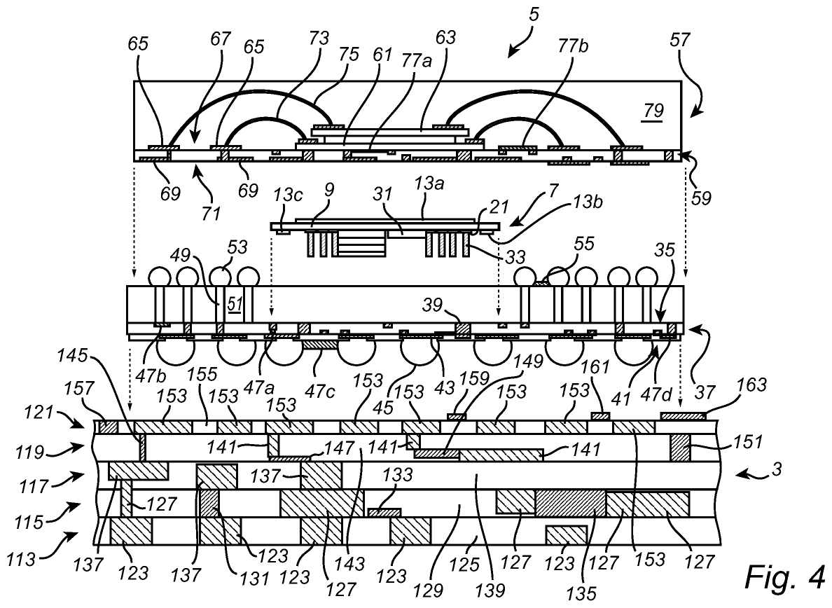

FIG. 4 is an exploded view of an electronic component 5 including the semiconductor assembly 7 in FIG. 3. As is schematically indicated in FIG. 4, the semiconductor assembly 7 is arranged on a first carrier surface 35 of a carrier 37 in such a way that a first set of carrier pads 39 on the first carrier surface 35 are connected to pads 21 of the first semiconductor die 9 in the semiconductor assembly 7, via conductive pillars 33. On a second carrier surface 41 opposite the first carrier surface 35, a second set of carrier pads 43 are provided. In the example configuration in FIG. 4, solder balls 45 are bonded to at least some of the carrier pads 43 in the second set of carrier pads. As shown in FIG. 4, the carrier 37 further comprises a first carrier capacitor 47a embedded in the carrier, a second carrier capacitor 47b on the first surface 35 of the carrier 37, and third 47c and fourth 47d carrier capacitors on the second surface 41 of the carrier 37. Some or all of the carrier capacitors may advantageously be discrete capacitor components.

In the example configuration of FIG. 4, the semiconductor assembly 7, as well as a number additional conductive pillars 49 are embedded in a dielectric material 51, and connectors, here in the form of balls 53, are provided on the conductive pillars 49. As is schematically illustrated in FIG. 4, a further capacitor 55 may be provided on the dielectric material 51 between adjacent balls 53.

A second semiconductor assembly 57 is connected to the balls 53, to provide additional functionality to the electronic component 5. As is schematically shown in FIG. 4, the second semiconductor assembly 57 comprises a carrier 59, a first semiconductor die 61 arranged on the carrier 59, and a second semiconductor die 63 stacked on the first semiconductor die 61. The carrier has a first set of carrier pads 65 on a first surface 67, and a second set of carrier pads 69 on a second surface 71 thereof. The first semiconductor die 61 is connected to pads in the first set of carrier pads 65 using bond wires 73, and the second semiconductor die 63 is connected to pads in the first set of carrier pads 65 using bond wires 75. The second set of carrier pads 69 are connected to the connectors 53. The carrier 59 comprises capacitors 77a-b, which may advantageously be discrete capacitor components. The first 61 and second 63 semiconductor dies, and the bond wires 73, 75 are embedded in a dielectric material 79.

As is schematically shown in FIG. 4, the electronic component 5 can be mounted on a circuit board 3 according to an example embodiment of the present invention. The exemplary circuit board 3, which may be a printed circuit board (PCB) or a substrate like PCB (SLP), is a layered structure comprising a first circuit board layer 113, a second circuit board layer 115, a third circuit board layer 117, a fourth circuit board layer 119, and a fifth circuit board layer 121.

As is schematically shown in FIG. 4, the first circuit board layer 113 includes a conductor pattern 123 embedded in a dielectric material 125. The second circuit board layer 115 includes a conductor pattern 127, and first 131, second 133, and third 135 discrete, low-profile capacitor components, all embedded in a dielectric material 129 of the second carrier layer. As will be understood to those skilled in the art, the discrete capacitor components 131, 133, 135 may be surface mounted on the first circuit board layer 113 using, per se, any suitable known mounting technique, and then embedded in the dielectric material of the second circuit board layer 115. The third circuit board layer 117 on the second circuit board layer 115 includes a conductor pattern 137, and a dielectric 139 embedding the conductor pattern 137. The fourth circuit board layer 119 includes a conductor pattern 141, and first 145, second 147, third 149, and fourth 151 discrete capacitor components, embedded in a dielectric material 143. The fifth circuit board layer 121 includes a conductor pattern 153, and a capacitor component 157 embedded in a dielectric material 155. Finally, on top of the fifth circuit board layer 121, first 159, second 161, and third 163 discrete capacitor components are mounted.

As was explained further above, aspects and embodiments of the present invention may benefit from the provision of very low profile capacitors. This applies to the semiconductor assembly according to embodiments of the present invention, the electronic component according to embodiments of the present invention, and the circuit board according to embodiments of the present invention. Such capacitors may advantageously be nanostructure-based.

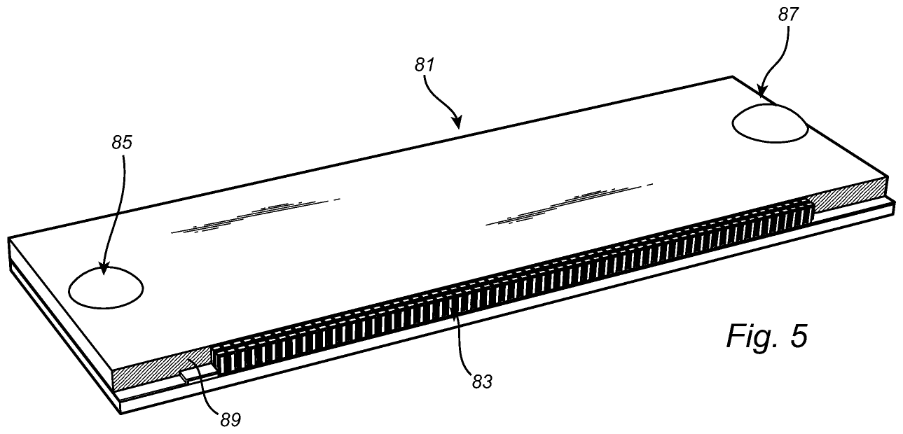

FIG. 5 is a schematic illustration of an example energy storage component, in the form of a MIM-capacitor component, which may be referred to as a carbon nano-fiber metal-insulator-metal (CNF-MIM) capacitor component, comprised in the semiconductor assembly according to embodiments of the present invention.

The energy storage component 81 in FIG. 5 is shown in the form of a discrete two-terminal MIM-capacitor component, comprising a MIM-arrangement 83, a first connecting structure, here in the form of a first bump 85, a second connecting structure, here in the form of a second bump 87, and a dielectric encapsulation material 89, at least partly embedding the MIM-arrangement 83. As can be seen in FIG. 5, the electrically insulating encapsulation material 89 at least partly forms an outer boundary surface of the energy storage component. The first 85 and second 87 connecting structures also at least partly forms the outer boundary surface of the energy storage component. Moreover, additional terminals not shown in the figure may conveniently be present in accordance with the present invention disclosure.

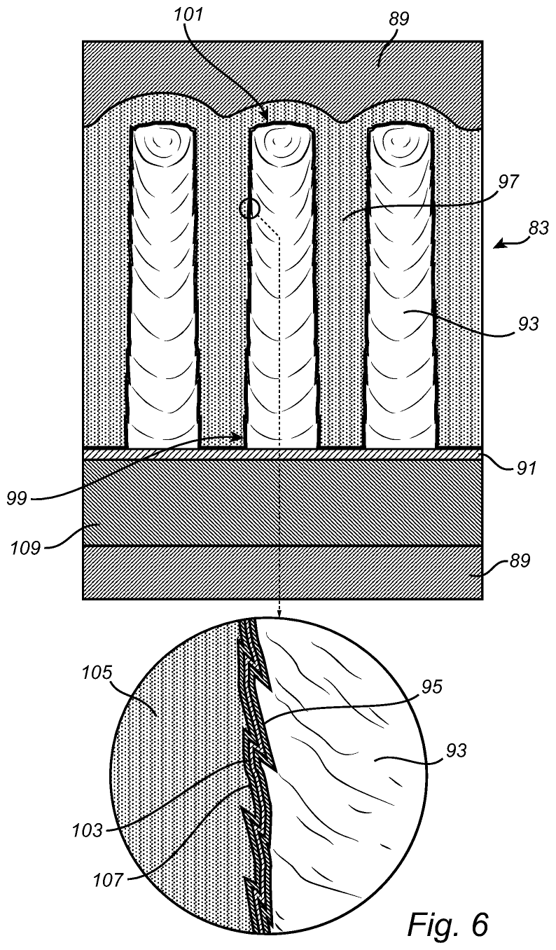

A first example configuration of the MIM-arrangement 83 will now be described with reference to FIG. 6. As is schematically shown in FIG. 6, the MIM-arrangement 83 comprises a first electrode layer 91, a plurality of conductive nanostructures 93 vertically grown from the first electrode layer 91, a solid dielectric material layer 95 conformally coating each nanostructure 93 in the plurality of conductive nanostructures and the first electrode layer 91 not covered by the conductive nanostructures 93, and a second electrode layer 97 covering the solid dielectric material layer 95. As can be seen in FIG. 6, the second electrode layer 97 completely fills a space between adjacent nanostructures more than halfway between a base 99 and a top 101 of the nanostructures 93. In the exemplary MIM-arrangement 83 in FIG. 6, the second electrode layer 97 completely fills the space between adjacent nanostructures 93, all the way from the base 99 to the top 101, and beyond.

As can be seen in the enlarged view of the boundary between nanostructure 93 and second electrode layer 97 in FIG. 6, the second electrode layer 97 comprises a first sublayer 103 conformally coating the solid dielectric material layer 95, a second sublayer 105, and a third sublayer 107 between the first sublayer 103 and the second sublayer 105.

Moreover, additional sub layer(s) for example as metal diffusion barrier not shown in the figure may conveniently be present in accordance with the present invention disclosure.

The dielectric material layer 95 may be a multi-layer structure, which may include sub-layers of different material compositions.

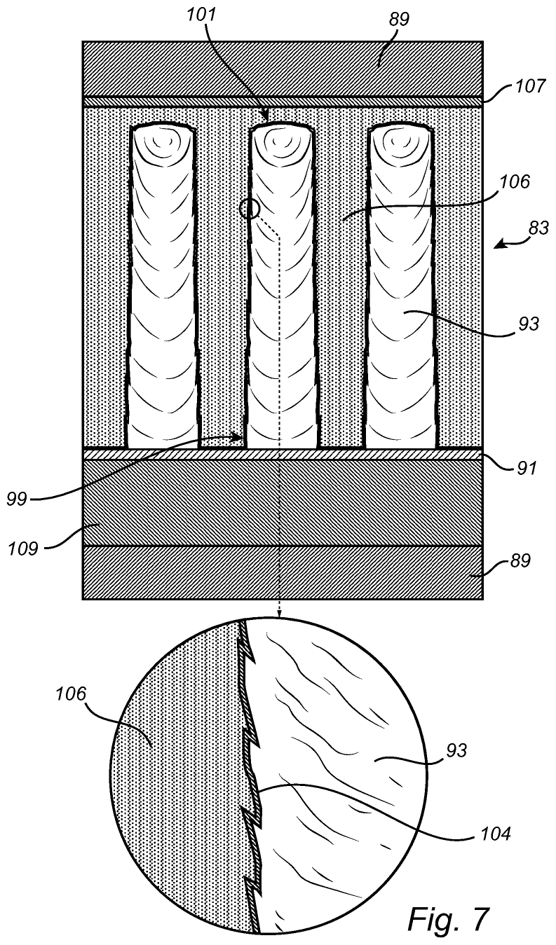

A second example configuration of the MIM-arrangement 83 will now be described with reference to FIG. 7. An energy storage component comprising the MIM-arrangement 83 in FIG. 7 is a MIM-electrochemical energy storage/battery component. As is schematically shown in FIG. 7, the MIM-arrangement 83 comprises a first electrode layer 91, a plurality of conductive nanostructures 93 vertically grown from the first electrode layer 91, an optional anode/cathode material layer 104 coating each nanostructure 93 in the plurality of conductive nanostructures and the first electrode layer 91 not covered by the conductive nanostructures 93, an electrolyte 106 covering the nanostructures 93, and a second electrode layer 97 covering the electrolyte 106. In the example embodiment of FIG. 7, the electrolyte 106 completely fills a space between adjacent nanostructures more than halfway between a base 99 and a top 101 of the nanostructures 93. In the exemplary MIM-arrangement 83 in FIG. 7, the electrolyte 106 completely fills the space between adjacent nanostructures 93, all the way from the base 99 to the top 101, and beyond. In embodiments, it may however be beneficial to provide the electrolyte 106 as a conformal coating on the nanostructures 93.

Moreover, additional sub layer(s) for example as metal diffusion barrier not shown in the figure may conveniently be present in accordance with the present invention disclosure.

A hybrid-component may include a MIM-arrangement 83 that is a combination of the MIM-arrangements in FIG. 6 and FIG. 7. For instance, the dielectric layer 95 in FIG. 6 may be provided between the nanostructures 93 and the electrolyte 106 in FIG. 7. Such a hybrid-component may further comprise an additional dielectric layer between the electrolyte 106 and the top electrode 107 in FIG. 7.

According to the present invention disclosures, in any of the present embodiments the electrically insulating encapsulation material at least partly forms an outer boundary surface of the energy storage component. It is also contemplated that each of the first connecting structure and the second connecting structure at least partly forms an outer boundary surface of the any of the embodiments of energy storage component. It is also admissible to from the first and second connecting structures to be present at the same surface or at the opposite surfaces from each other. The first and second connecting structures may partially form the side walls of the component. The present invention contemplates to accommodate to have more number of connecting structures if required by the design.

The person skilled in the art realizes that the present invention by no means is limited to the preferred embodiments described above. On the contrary, many modifications and variations are possible within the scope of the appended claims.

In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

What is claimed is:

1. A semiconductor assembly, comprising:
a first semiconductor die including processing circuitry and pads, said first semiconductor die having a first surface and a second surface opposite the first surface;
a second semiconductor die circuitry and pads, said second semiconductor die being arranged on one of the first surface and the second surface of said first semiconductor die, and pads of said second semiconductor die being coupled to pads of said first semiconductor die; and
at least a first energy storage component having terminals, said first energy storage component being arranged on one of the first surface and the second surface of said first semiconductor die and the terminals of said energy storage component being coupled to pads of said first semiconductor die.

2. The semiconductor assembly according to claim 1, wherein the processing circuitry is on the first surface of said first semiconductor die, and said first energy storage component is arranged on the first surface of said first semiconductor die.

3. The semiconductor assembly according to claim 2, wherein said first energy storage component is arranged on the second surface of said first semiconductor die.

4. The semiconductor assembly according to claim 2, further comprising:
a second energy storage component having terminals, said second energy storage component being arranged on the second surface of said semiconductor die and the terminals of said energy storage component being coupled to pads of said first semiconductor die.

5. The semiconductor assembly according to claim 1, wherein the processing circuitry is on the first surface of said first semiconductor die, and said second semiconductor die is arranged on the first surface of said semiconductor die.

6. The semiconductor assembly according to claim 1, further comprising:
a third semiconductor die including circuitry and pads, said third semiconductor die being arranged on one of the first surface and the second surface of said first semiconductor die, and pads of said third semiconductor die being coupled to pads of said first semiconductor die.

7. The semiconductor assembly according to claim 6, wherein said third semiconductor die comprises power management circuitry, digital circuitry, RF circuitry and/or sensing circuitry.

8. The semiconductor assembly according to claim 1, wherein said at least first energy storage component is a nanostructure-based energy storage component.

9. The semiconductor assembly according to claim 8, wherein said at least first energy storage component comprises:
a first electrode layer, coupled to a first terminal of said first energy storage component;
a plurality of conductive nanostructures conductively connected to said first electrode layer;
a second electrode layer, coupled to a second terminal of said first energy storage component; and
a conduction controlling material arranged between said plurality of conductive nanostructures and said second electrode layer.

10. The semiconductor assembly according to claim 9, wherein said conduction controlling material is a dielectric material electrically separating said plurality of conductive nanostructures and said second electrode layer,
wherein said energy storage component is a capacitor component.

11. The semiconductor assembly according to claim 10, wherein:
said dielectric material is a solid dielectric material conformally coating each nanostructure in said plurality of nanostructures; and
said second electrode layer covers said dielectric material.

12. The semiconductor assembly according to claim 1, wherein said at least one energy storage component is a discrete component.

13. The semiconductor assembly according to claim 1, wherein the first semiconductor die is a system on chip (SoC) or silicon in package (SiP).

14. An electronic component comprising:
a carrier having at least a first set of carrier pads on a first carrier surface; and
the semiconductor assembly according to claim 1, arranged on the first carrier surface, pads of said first semiconductor die being coupled to said first set of carrier pads.

15. The electronic component according to claim 14, wherein said carrier comprises an energy storage component having terminals.

16. The electronic component according to claim 15, wherein a terminal of said energy storage component is coupled to a pad in said first set of carrier pads.

17. The electronic component according to claim 15, wherein the energy storage component is embedded in said carrier.

18. The electronic component according to claim 15, wherein the energy storage component is arranged on a surface of said carrier.

19. The electronic component according to claim 18, wherein the energy storage component is arranged between said carrier and said semiconductor assembly.

20. The electronic component according to claim 14, wherein the energy storage component comprised in said carrier is a nanostructure-based energy storage component.

21. The electronic component according to claim 20 wherein the energy storage component comprises:
a first electrode layer, coupled to a first terminal of said energy storage component;
a plurality of conductive nanostructures conductively connected to said first energy storage component electrode layer;
a second electrode layer, coupled to a second terminal of said energy storage component; and
a conduction controlling material arranged between said plurality of conductive nanostructures and said second electrode layer.

22. The electronic component according to claim 21, wherein said conduction controlling material is a dielectric material electrically separating said plurality of conductive nanostructures and said second electrode layer,
wherein said energy storage component is a capacitor component.

23. The electronic component according claim 14, wherein said carrier is an interposer having a second set of carrier pads on a second carrier surface, opposite said first carrier surface, said second set of carrier pads being coupled to said first set of carrier pads.

24. The electronic component according to claim 14, wherein said carrier is a printed circuit board (PCB) or a substrate like pcb (SLP).

25. The electronic component according to claim 14, wherein said semiconductor assembly is embedded in a dielectric.

26. The electronic component according to claim 14, further comprising a second semiconductor assembly arranged on top of said semiconductor assembly.

27. The electronic component according to claim 14, wherein said second semiconductor assembly comprises:
a first semiconductor die including processing circuitry and pads, said first semiconductor die having a first surface and a second surface opposite the first surface; and
at least a first energy storage component having terminals, said first energy storage component being arranged on one of the first surface and the second surface of said first semiconductor die and the terminals of said energy storage component being coupled to pads of said first semiconductor die.

28. An electronic device, comprising the electronic component according to claim 14 mounted on a circuit board.

29. A circuit board comprising:
a first circuit board layer; and
a second circuit board layer layered with the first circuit board layer, the second circuit board layer including a conductor pattern, at least one discrete energy storage component, and a dielectric material embedding the conductor pattern and the discrete energy storage component.

30. The circuit board according to claim 29, wherein said at least one discrete energy storage component is surface mounted on said first circuit board layer.

31. The circuit board according to claim 29, wherein said first circuit board layer includes a conductor pattern, and a dielectric material embedding the conductor pattern.

32. The circuit board according to claim 31, wherein:
said first circuit board layer additionally includes at least one discrete energy storage component; and
the dielectric material embeds the discrete energy storage component.

33. The circuit board according to claim 29, wherein said second circuit board layer includes a plurality of discrete energy storage components, each being embedded by the dielectric material of said second circuit board layer.

34. The circuit board according to claim 29, wherein the at least one discrete energy storage component is a nanostructure-based energy storage component.

35. The circuit board according to claim 34, wherein the energy storage component comprises:
a first electrode layer, coupled to a first terminal of said energy storage component;
a plurality of conductive nanostructures conductively connected to said first electrode layer;
a second electrode layer, coupled to a second terminal of said energy storage component; and
a conduction controlling material arranged between said plurality of conductive nanostructures and said second electrode layer.
